(19) United States
(12) Patent Application Publication
(10) Pub. No.: US 2014/0038430 A1
(43) Pub. Date: Feb. 6, 2014

(54) METHOD FOR PROCESSING OBJECT

(71) Applicant: TOKYO ELECTRON LIMITED, Minato-ku (JP)

(72) Inventors: Yoshiro Kabe, Yamanashi (JP); Taichi Monden, Yamanashi (JP); Kouji Shimomura, Yamanashi (JP); Kentaro Shiraga, Yamanashi (JP); Yoshimasa Watanabe, Yamanashi (JP); Yoshihiro Hirota, Yamanashi (JP); Junichi Kitagawa, Yamanashi (JP)

(73) Assignee: TOKYO ELECTRON LIMITED, Minato-ku (JP)

(21) Appl. No.: 13/945,256

(22) Filed: Jul. 18, 2013

(30) Foreign Application Priority Data
Aug. 1, 2012 (JP) 2012-171107

(51) Int. Cl. H01L 21/268

(52) U.S. Cl. CPC H01L 21/268
USPC 438/795

(57) ABSTRACT

In a method for processing an object by heating the object, microwaves are irradiated to the object. In the microwave irradiation, the object is forcedly cooled.

### CROSS-REFERENCE TO RELATED APPLICATION

This application claims priority to Japanese Patent Application No. 2012-171107 filed on Aug. 1, 2012, the entire content of which is incorporated herein by reference.

### FIELD OF THE INVENTION

The present invention relates to a method for processing an object by using a microwave.

### BACKGROUND OF THE INVENTION

In a semiconductor wafer (hereinafter, simply referred to as “wafer”) as an object to be processed, crystallization of amorphous silicon or activation of doped impurities is generally realized by heat treatment of irradiating heat rays to the wafer. The heat rays irradiated to the wafer crystallize amorphous silicon by heating and fusing and also activate portions doped with impurities by heating. The irradiation of heat rays to the wafer is performed by using, e.g., a lamp heater.

However, in the heat treatment using a lamp heater, heat rays are irradiated to the surface of the wafer and, thus, a shape of a trench or a hole on the surface of the wafer may collapse.

To that end, there has been used flash annealing (instantaneous heat treatment) that prevents unnecessary heat from being applied to the wafer by using instantaneous heat treatment. In this case, however, heat may not be sufficiently supplied to impurities or amorphous silicon inside the wafer and, thus, the crystallization or the activation may be insufficient.

Accordingly, treatment using a microwave is being studied (see, e.g., Japanese Patent Application No. 2012-040095). In case of the treatment using a microwave, when dipoles of impurities exist in a wafer to which microwaves are irradiated, the dipoles are vibrated by the microwaves, thereby generating kinetic energy. The vicinity of the dipoles is heated by thermal energy converted from the kinetic energy (dielectric heating). In other words, by positioning dipoles at a portion of the wafer which needs to be heated, only the corresponding portion can be selectively heated.

Further, the present inventors have found that the treatment using a microwave provides unique effects that cannot be obtained by the above-described heating, e.g., crystallization facilitation effect or activation facilitation effect by microwaves. Therefore, when the treatment using a microwave is performed on the wafer, the crystallization or the activation may be facilitated without particularly increasing the heat treatment temperature of the wafer.

However, when the wafer has a portion through which current flows, e.g., a conductive layer, an eddy current may be generated at the conductive layer by electromagnetic induction from the microwaves. When the eddy current flows through the conductive layer, heat corresponding to resistance of the conductive layer is generated (induction heating).

In other words, when the microwaves are irradiated to the wafer in order to obtain the unique effects of the microwaves, the wafer is excessively heated by induction heating and, thus, crystallization or activation is extremely facilitated. As a result, the unique effects of the microwaves which facilitate the crystallization or the activation by the microwaves are relatively suppressed.

### SUMMARY OF THE INVENTION

In view of the above, the present invention provides a method for processing an object, which can reliably obtain unique effects due to microwaves.

In accordance with a first aspect of the present invention, there is provided a method for processing an object by heating the object, including: irradiating microwaves to the object, wherein the object is forcedly cooled.

In accordance with a second aspect of the present invention, there is provided a method for processing an object by heating the object having amorphous silicon, including: crystallizing the amorphous silicon by irradiating microwaves to the object, which includes generating crystal nuclei at the silicon amorphous; and growing the generated crystal nuclei, wherein, at least in said growing the crystal nuclei, the object is forcedly cooled.

### BRIEF DESCRIPTION OF THE DRAWINGS

The above and other objects and features of the present invention will become apparent from the following description of embodiments, given in conjunction with the accompanying drawings, in which:

FIG. 1 is an enlarged partial cross sectional view of a wafer to which a method for processing an object to be processed in accordance with a first embodiment of the present invention is applied;

FIG. 2 is a graph showing relationship between heat treatment temperatures of a wafer and crystallization times in the case of heat treatment using a lamp heater and in the case of heat treatment using a microwave;

FIG. 3 is a cross sectional view schematically showing a microwave heating apparatus for performing the method for processing an object to be processed in accordance with the first embodiment of the present invention;

FIG. 4 is a view to explain the method for processing an object to be processed in accordance with the first embodiment of the present invention;

FIG. 5 is a graph showing relationship between a heat treatment process of a wafer and a generation speed or a growth speed of crystal nucleus in amorphous silicon;

FIG. 6 is an enlarged partial cross sectional view of a wafer to which a method for processing an object to be processed in accordance with a second embodiment of the present invention;

FIG. 7 is a graph showing relationship between a heat treatment temperature of a silicon wafer and a sheet resistance in the case of heat treatment using a lamp heater and in the case of heat treatment using a microwave; and

FIG. 8 is a graph showing degree of diffusion of impurities in heat treatment using a lamp heater and heat treatment using a microwave and including forced cooling.

### DETAILED DESCRIPTION OF THE EMBODIMENTS

Hereinafter, embodiments of the present invention will be described with reference to the accompanying drawings.

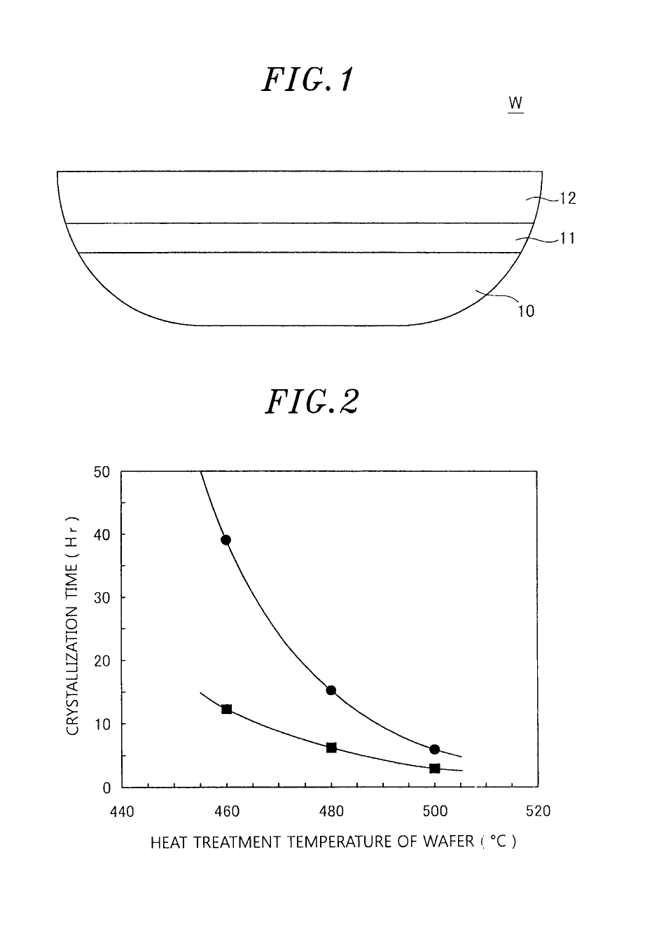

First, the present inventors have obtained data in the case of performing crystallization of an amorphous silicon layer 12 in a wafer W (object to be processed), in which a silicon base layer 10, a silicon oxide layer 11 and the amorphous silicon layer 12 are formed in that order from the bottom as shown in FIG. 1, by heat treatment using a lamp heater and treatment using a microwave. The graph of FIG. 2 which will be described later shows crystallization time obtained in the case of maintaining the heat treatment temperature of the wafer W to about 460° C., 480° C. and 500° C. in the heat treatment using a lamp heater and in the treatment using a microwave. Further, in the treatment using a microwave, the surface of the wafer W is forcedly cooled by injecting cooling gas.

Moreover, amorphous silicon is generally not polarized. But, amorphous silicon in the vicinity (interface) of a crystal is polarized. In the wafer W, amorphous silicon of the amorphous silicon layer 12 which is close to the silicon oxide layer 11 is polarized. The microwave makes the polarized amorphous silicon vibrate to generate thermal energy. The amorphous silicon is fused and crystallized by the thermal energy. Next, amorphous silicon near the crystallized silicon is polarized and vibrated by the microwave. In other words, in the amorphous silicon layer 12 of the wafer W, the crystallization progresses from the vicinity of the boundary with the silicon oxide layer 11.

FIG. 2 is a graph showing relationship between crystallization times and heat treatment temperatures of a wafer in the heat treatment using a lamp heater and in the treatment using a microwave, respectively. The crystallization time in the heat treatment using a lamp heater is expressed by ┌┘, and that in the treatment using a microwave is expressed by ┌▪┘.

As can be seen from FIG. 2, at any of the heat treatment temperatures of the wafer W, the crystallization time is shorter in the treatment using a microwave than in the heat treatment using a heater. When the heat treatment temperature of the wafer W is the same, it is expected that the crystallization time is the same because the thermal energy applied to the amorphous silicon 12 is the same. Therefore, it is assumed that the crystallization time becomes shorter in the treatment using a microwave due to other crystallization facilitation effect than that of heating, i.e., due to the unique effect of the microwaves which facilitates crystallization.

Further, as the heat treatment temperature of the wafer W gets lower, the difference of the crystallization time between the heat treatment using a lamp heater and the treatment using a microwave is increased. This is because the unique effect of facilitating crystallization due to the microwaves is enhanced as the heat treatment temperature of the wafer W gets lower.

The present invention has been conceived based on the above information.

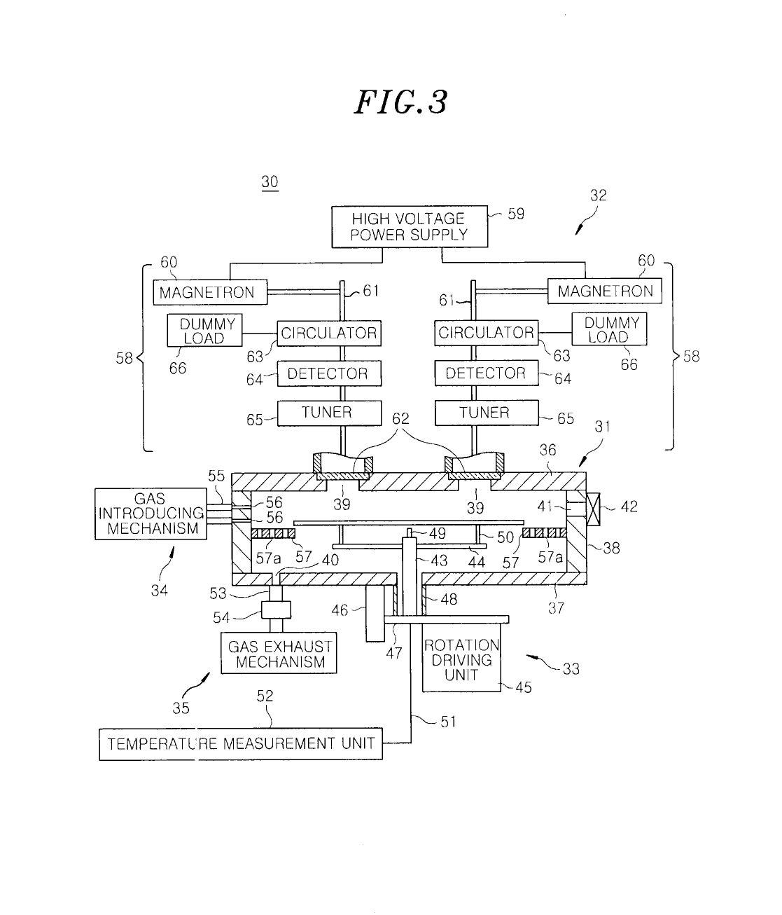

FIG. 3 is a cross sectional view schematically showing a microwave heating apparatus for performing the method for processing an object in accordance with the present embodiment.

Referring to FIG. 3, a microwave heating apparatus 30 includes: a processing chamber 31 for accommodating therein a wafer W; a microwave introducing mechanism 32 for introducing microwaves into the processing chamber 31; a supporting mechanism 33 for supporting a wafer W in the processing chamber 31; a gas introducing mechanism 34 for introducing a predetermined gas into the processing chamber 31; and a gas exhaust mechanism 35 for evacuating the processing chamber 31.

The processing chamber 31 has a plate-shaped ceiling portion 36, a bottom portion 37 opposite to the ceiling portion 36, and sidewalls 38 for connecting the ceiling portion 36 and the bottom portion 37. The processing chamber 31 has a rectangular parallelepiped shape. The ceiling portion 36, the bottom portion 37 and the sidewalls 38 are made of metal, e.g., aluminum or stainless steel. The ceiling portion 36 has a plurality of microwave inlet ports 39 penetrating therethrough in a vertical direction in FIG. 3 (hereinafter, simply referred to as “vertical direction”). The bottom portion 37 has a gas exhaust port 40. The inner surface of each of the sidewalls 38 is flat so as to reflect the microwaves introduced into the processing chamber 31. Further, a loading/unloading port 41 of the wafer W is provided at one of the sidewalls 38. A gate valve 42 is provided at the loading/unloading port 41 to open and close the loading/unloading port 41.

The supporting mechanism 33 has a shaft 43 extending through the bottom portion 37 along the vertical direction, a plurality of arms 44 extending in a horizontal direction in FIG. 3 from an upper portion of the shaft 43, a rotation driving unit 45 for rotating the shaft 43, an elevation driving unit 46 for vertically moving the shaft 43, and a shaft base portion 47, to which the rotation driving unit 45 and the elevation driving unit 46 are attached, serving as a base of the shaft 43. The shaft 43 is isolated from the outside of the processing chamber 31 by a bellows 48 covering the shaft 43.

In the supporting mechanism 33, the wafer W is supported by pins 50 protruding from the leading ends of the arms 44. The wafer W mounted on the arms 44 is rotated, in a horizontal plane in FIG. 3, by the rotation of the shaft 43 in the processing chamber 31 and moved in the vertical direction by the vertical movement of the shaft 43 in the processing chamber 31. Further, a radiation thermometer 49 for measuring a temperature of the wafer W is provided at the leading end of the shaft 43. The radiation thermometer is connected through wiring 51 to a temperature measurement unit 52 provided outside the processing chamber 31.

The gas exhaust mechanism 35 has a dry pump and is connected to a gas exhaust port 40 through a gas exhaust line 53. A pressure control valve 54 is provided in the gas exhaust line 53 to control a pressure in the processing chamber 31. Moreover, it is not necessary to provide the gas exhaust mechanism 35 at the microwave heating apparatus 30. When the gas exhaust mechanism 35 is not provided, a gas exhaust line of gas exhaust equipment in a factory where the microwave heating apparatus 30 is installed is directly connected to the gas exhaust port 40.

The gas introducing mechanism 34 is connected to a plurality of gas inlet ports 56 that open in the sidewall 38 through a plurality of lines 55. Accordingly, a processing gas or a cooling gas, e.g., N₂ gas, Ar gas, He gas, Ne gas, O₂ gas or H₂ gas, is introduced into the processing chamber 31 in a sideflow manner. Each of the lines 55 is provided with a mass flow controller (not shown) or an opening/closing valve (not shown), and a type and a flow rate of the processing gas or the cooling gas are controlled. In FIG. 3, the gas inlet ports 56 open in the sidewall 38. However, a plurality of gas inlet ports may open in the ceiling portion 36 so that the processing gas or the cooing gas may be introduced into the processing chamber 31 in a downflow manner. Or, a stage for mounting a wafer W thereon may be provided at the supporting mechanism 33 and a plurality of gas inlet ports may open in the mounting surface of the stage so that the cooling gas may be introduced into the processing chamber 31 in an upflow manner.

In the processing chamber 31, a rectifying plate 57 is provided between the arms 44 and the sidewalls 38. The rectifying plate 57 has a plurality of through holes 57a. The flow of atmosphere near the wafer W is regulated by allowing atmosphere in the processing chamber 31 to flow through the through holes 57a.

The microwave introducing mechanism 32 is disposed above the ceiling portion 36 and includes a plurality of microwave units 58 for introducing microwaves into the processing chamber 31 and a high voltage power supply 59 connected to the microwave units 58.

Each of the microwave units 58 has a magnetron 60 for generating microwaves, a waveguide 61 for transmitting the generated microwaves to the processing chamber 31, and a transmission window 62 fixed to the ceiling portion 36 so as to block the microwave inlet ports 39.

The magnetrons 60 are connected to the high voltage power supply 59. Using a high voltage current supplied from the high voltage power supply 59, the magnetrons 60 generate microwaves of various frequencies, e.g., 2.45 GHz or 5.8 GHz. The magnetrons 60 selectively generate a microwave having a frequency suitable for heat treatment performed by the microwave heating apparatus 30.

The waveguide 61 has a rectangular cross section and a square column shape. The waveguide 61 is installed upward from the microwave inlet port 39 to connect the magnetron 60 and the transmission window 62. Each of the magnetron 60 is disposed near the upper end of the corresponding waveguide 61. The microwaves generated by the magnetron 60 are transmitted through the corresponding waveguide 61 and introduced into the processing chamber 31 through the transmission window 62.

The transmission window 62 is made of a dielectric material, e.g., quartz or ceramic. The gap between the transmission window 62 and the ceiling portion 36 is airtightly sealed by a sealing member. The distance from the transmission window 62 to the wafer W supported by the arms 44 is preferably, e.g., about 25 mm or above.

Each of the microwave units 58 further has a circulator 63, a detector 64, a tuner 65 and a dummy load 66 connected to the circulator 63. The circulator 63, the detector 64 and the tuner 65 are sequentially arranged on the waveguide 61 in that order from the top. The circulator and the dummy load 66 serve as isolators of the microwaves reflected from the inside of the processing chamber 31. The dummy load 66 converts the reflected waves separated from the waveguide 61 by the circulator 63 into heat to be consumed.

The detector 64 detects the reflected waves from the inside of the processing chamber 31, and the tuner 65 adjusts an impedance between the magnetron 60 and the processing chamber 31. The tuner 65 has a conductor plate (not shown) that can protrude into the waveguide 61 and adjusts the impedance by controlling the protrusion amount of the conductor plate such that the power of the reflected wave is minimized.

In the microwave heating apparatus 30, the microwaves introduced into the processing chamber 31 are reflected by the inner surfaces of the sidewalls 38 and the like and scattered. The scattered microwaves are omnidirectionally irradiated to the wafer W. The microwaves irradiated to the wafer W vibrate dipoles in the wafer W, thereby generating kinetic energy. The wafer W is heated by heat energy converted from the kinetic energy. In other words, the heat treatment using a microwave is carried out. At this time, the shaft 43 is rotated to rotate the wafer W in the horizontal plane in FIG. 3 so that the scattered microwaves can be irradiated to each portion of the wafer W. When the inside of the processing chamber 31 where the microwaves are scattered is depressurized, abnormal discharge may occur. Therefore, when the microwaves are irradiated to the wafer W, the inside of the processing chamber 31 is maintained substantially at the atmospheric pressure by the pressure control valve 54 of the gas exhaust mechanism 35.

In the method for processing an object in accordance with the present embodiment, when the microwave heating apparatus 30 performs the treatment using a microwave, the gas introducing mechanism 34 introduces a cooling gas into the processing chamber 31 through the gas inlet ports 56 and forcedly cools the surface of the wafer W. Further, the term “the surface of the wafer W” used in the present embodiment is not limited to the top surface of the wafer W and may include the bottom surface of the wafer W.

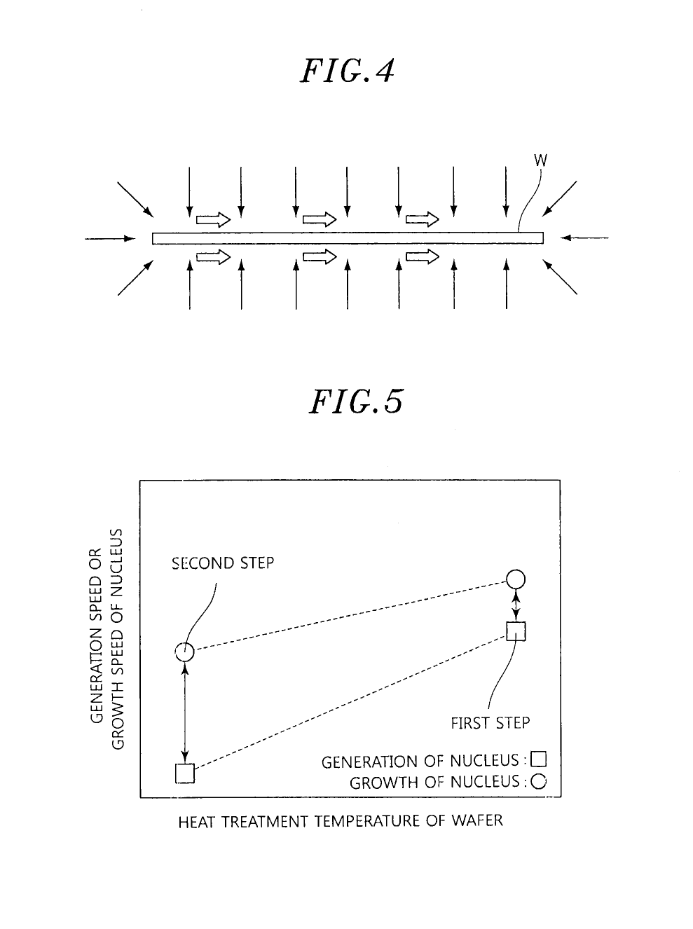

FIG. 4 is a view to explain the method for processing an object in accordance with the present embodiment.

Referring to FIG. 4, the microwaves (indicated by thin arrows) scattering in the processing chamber 31 are omnidirectionally irradiated to the wafer W supported by the pins 50 of the arms 44. The irradiated microwaves are absorbed by the wafer W and vibrate polarized amorphous silicon near the boundary with the silicon oxide film 11, thereby generating thermal energy. The amorphous silicon is fused and crystallized by the thermal energy. As described above, in the amorphous silicon layer 12, the crystallization progresses from the vicinity of the boundary with the silicon oxide layer 11.

At this time, an eddy current is generated at the amorphous silicon layer 12 by the microwaves. Due to the flow of the eddy current in the amorphous silicon layer 12, heat is generated. Since, however, the cooling gas (indicated by thick arrows in FIG. 4) introduced into the processing chamber 31 flows along the amorphous silicon layer 12 exposed on the surface of the wafer W, the heat generated by the eddy current is removed. In other words, the wafer W is forcedly cooled by the cooling gas. As a consequence, the induction heating to the wafer W is suppressed, and the crystallization by the induction heating is not extremely facilitated, which relatively increases the unique effect of the microwaves which facilitates crystallization. Accordingly, the unique effect of the microwave which facilities crystallization can be reliably obtained, and the crystallization can be facilitated without particularly increasing the temperature of the wafer W. As a result, the collapse of the shape of the trench or the hole on the surface of the wafer W can be prevented.

Further, when silicon is heated to a high temperature, e.g., about 600° C. or above, thermal electrons are generated in silicon. Since the thermal electrons electrically function as metal, the microwaves are reflected. Accordingly, the treatment using a microwave cannot be performed on the wafer W, and the amount of microwaves that are not absorbed by the wafer W is increased in the processing chamber 31. This increases the possibility of abnormal discharge. However, in the method for processing an object in accordance with the present embodiment, the wafer W is forcedly cooled by the cooling gas, so that the generation of thermal electrons is suppressed and the wafer W does not electrically function as metal. As a consequence, the microwaves can be reliably absorbed by the wafer W and, also, the increase of the amount of microwaves remaining in the processing chamber 31 can be prevented.

In the method for processing an object in accordance with the present embodiment, the microwave having a frequency of 2.45 GHz or 5.8 GHz may be used. Since, however, a microwave having a low frequency is not easily absorbed by the object to be processed, it is preferable to use a microwave having a frequency of 5.8 GHz. Accordingly, the unique effect of the microwaves which facilitates crystallization can be further enhanced and, also, the increase of the amount of microwaves that remain in the processing chamber 31 without being absorbed by the wafer W can be prevented.

In the method for processing an object in accordance with the present embodiment, the heat generated by induction heating in the amorphous silicon layer 12 exposed on the surface of the wafer W is removed by the cooling gas. However, the layer in which heat is generated by induction heating may not be exposed on the surface of the wafer W. In this case, the heat generated in the corresponding layer by induction heating is transmitted to the surface of the wafer W via another layer and removed by the cooling gas.

Next, a modification of the method for processing an object in accordance with the present embodiment will be described. The modification is also performed by the microwave heating apparatus 30 shown in FIG. 3.

When a polysilicon thin film used for a TFT (Thin Film Transistor) or the like is formed by directly depositing polysilicon, crystallization does not occur. Therefore, a crystallization grain size is not increased in the polysilicon thin film, and sufficient mobility cannot be obtained.

Therefore, there has been developed a method for forming an amorphous silicon thin film by depositing amorphous silicon and then crystallizing the amorphous silicon by heat treatment. In this method, the crystallization is carried out by two steps, i.e., the generation of crystal nuclei in the amorphous silicon thin film and the growth of the generated crystal nuclei.

Further, as shown in the graph of FIG. 5, the generation speed and the growth speed of the crystal nucleus in the amorphous silicon are in proportion to the heat treatment temperature of the wafer W. Meanwhile, the increase in the generation speed of the crystal nuclei is easily affected by the heat treatment temperature of the wafer W compared to the increase in the growth speed of the crystal nucleus. Therefore, the generation speed of the crystal nucleus can be preferentially increased at a higher heat treatment temperature of the wafer W. The growth speed of the crystal nucleus can be preferentially increased at a lower heat treatment temperature of the wafer W.

Further, the activation energy of the generation of the crystal nucleus is about 5.1 eV, and the activation energy of the growth of the crystal nucleus is about 3.9 eV. Accordingly, in view of the activation energy, when the generation speed of the crystal nucleus needs to be increased, it is required to increase the heat treatment temperature of the wafer W and set the amount of heat energy added to the amorphous silicon thin film to be greater than about 5.1 eV. When the growth of the crystal nucleus is preferential over the generation of the crystal nucleus, it is preferable to decrease the heat treatment temperature of the wafer W and set the amount of thermal energy added to the amorphous silicon thin film to be greater than about 3.9 eV and smaller than about 5.1 eV.

Therefore, in the polysilicon thin film forming method as the modification of the method for processing an object in accordance with the present embodiment, first, an amorphous silicon thin film is formed on the wafer W and, then, the treatment using a microwave is performed on the wafer W by the microwave heating apparatus 30. However, in the treatment using a microwave, first, the amount of thermal energy added to the amorphous silicon thin film is increased by increasing the amount of microwave irradiated to the wafer W, so that a heat treatment temperature of the wafer W is increased and a required number of crystal nuclei is quickly generated (“first step” in FIG. 5) (crystal nucleus generation step). Next, the amount of thermal energy added to the amorphous silicon thin film is decreased by decreasing the amount of microwave irradiated to the wafer W. This decreases the heat treatment temperature of the wafer W, so that the growth of crystal nuclei is preferentially carried out over the generation of crystal nuclei. As a result, the generated crystal nuclei are grown while suppressing the generation of crystal nuclei (“second step” in FIG. 5) (crystal nucleus growth step).

When a large number of crystal nuclei are generated, the number of finally formed crystals is increased and, thus, a grain size of each crystal is decreased. However, in the modification of the method for processing an object in accordance with the present embodiment, the generation of crystal nucleus is suppressed by decreasing the heat treatment temperature of the wafer W by decreasing the amount of microwaves during the treatment using a microwave. Accordingly, the increase in the number of finally formed crystals is prevented and the grain size of each crystal can be increased.

Further, in the modification of the method for processing an object in accordance with the present embodiment, the surface of the wafer W is forcedly cooled by introducing a cooling gas into the processing chamber 31 in the second step, so that the induction heating of the wafer W is suppressed. Accordingly, the unique effect of microwaves which facilitates crystallization can be enhanced, and the crystal nuclei are quickly grown.

In other words, in the modification of the method for processing an object in accordance with the present embodiment, quick generation and quick growth of crystal nuclei can be realized by firstly increasing the amount of microwaves irradiated to the wafer W and then decreasing the same. As a result, the crystallization time can be shortened.

Moreover, as described above, when a large number of crystal nuclei are generated, the grain size of the finally formed crystal becomes small. Therefore, it is preferable to minimize the time of the first step.

In the modification of the method for processing an object in accordance with the present embodiment, the cooling gas is introduced into the processing chamber 31 only in the second step. However, the cooling gas may also be introduced into the processing chamber 31 in the first step. In this case, the flow rate of the cooling gas introduced in the second step is set to be greater than that of the cooling gas introduced in the first step. Accordingly, the heat treatment temperature of the wafer W in the second step can be lower than that of the wafer W in the first step, and the unique effect of microwaves which facilitates crystallization can be further enhanced in the second step.

Further, in the modification of the method for processing an object in accordance with the present embodiment, the amount of microwaves irradiated to the wafer W may not be changed. In this case, the cooling gas is introduced into the processing chamber 31 only in the second step. Alternatively, the flow rate of the cooling gas introduced in the second step may be set to be greater than that of the cooling gas introduced in the first step. Accordingly, the heat treatment temperature of the wafer W in the first step can be increased, and that of the wafer W in the second step can be decreased. As a result, the grain size of each crystal can be increased and, also, quick generation and quick growth of crystal nuclei can be realized.

Next, a method for processing an object in accordance with a second embodiment of the present invention will be described. In the method for processing an object in accordance with the second embodiment is also performed by the microwave heating apparatus 30 shown in FIG. 3.

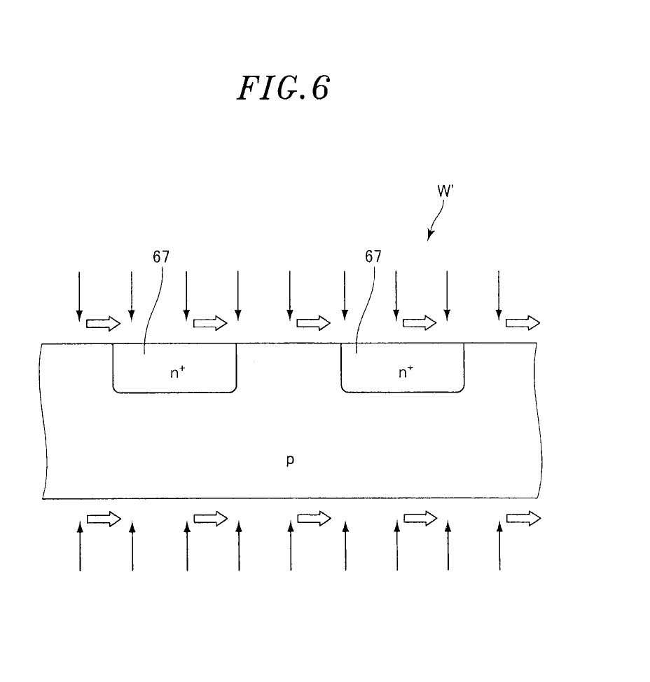

FIG. 6 is an enlarged partial cross sectional view of a wafer to which the method for processing an object in accordance with of the second embodiment is applied.

Referring to FIG. 6, impurities are doped on portions 67 of a surface of a wafer W′ which is formed of a single crystal silicon base in order to form source and drain of MOSFET. In the method for processing an object in accordance with the second embodiment, the impurities doped on the portions 67 are activated, so that the portions 67 are deformed into N-type silicon to function as source or drain.

As described above, the heat treatment using a microwave provides the unique crystallization facilitation effect. Meanwhile, the activation of impurities corresponds to a kind of crystallization because it is a process that makes doped impurities function as carriers by substituting the doped impurities for silicon crystal lattice points. Accordingly, the heat treatment using a microwave can provide the effect of facilitating activation of impurities.

Therefore, the present inventors have performed the heat treatment using a lamp heater and the treatment using a microwave in order to activate impurities doped on the portions of the surface of the single crystal silicon substrate. Further, in the treatment using a microwave, the activation was performed in both the case where the surface of the silicon substrate was forcedly cooled by injecting a cooling gas and the case where no cooling gas was injected. The relationship between the sheet resistance and the heat treatment temperature of the silicon substrate was obtained by measuring the sheet resistance as an index of activation both in the heat treatment using a lamp heater and in the treatment using a microwave (both the case where the forced cooling was performed, and the case where the forced cooling was not performed).

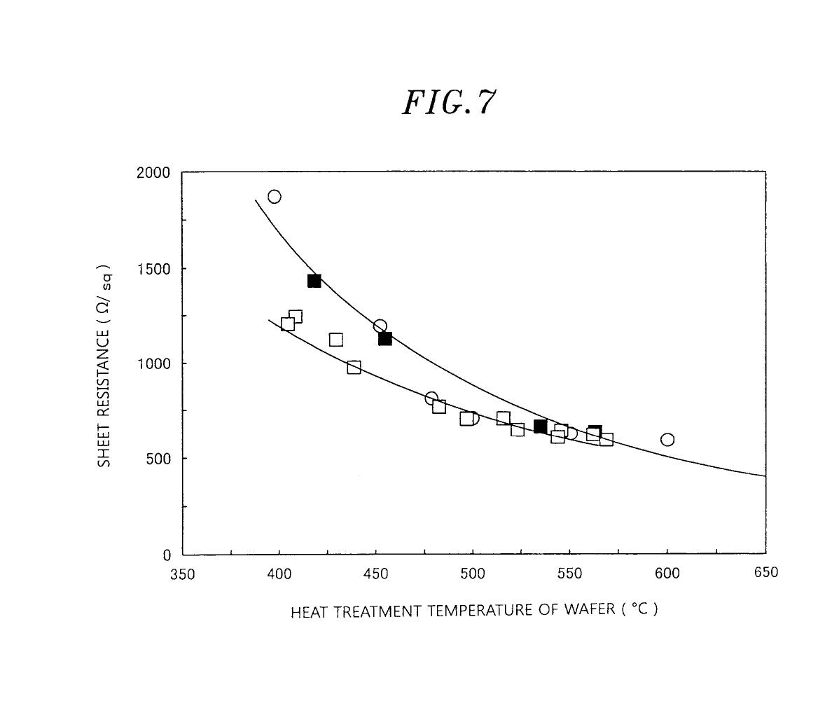

FIG. 7 is a graph showing the relationship between the sheet resistance and the heat treatment temperature of the silicon substrate in the heat treatment using a lamp heater and in the treatment using a microwave. The sheet resistance measured in the heat treatment using a lamp heater is indicated by ┌◯┘; the sheet resistance measured in the heat treatment using a microwave without the forced cooling is indicated by ┌▪┘; and the sheet resistance measured in the heat treatment using a microwave with the forced cooling is indicated by ┌□┘.

As can be seen from FIG. 7, in regards to most heat treatment temperatures of the silicon substrate, the sheet resistance is lower in the heat treatment using a microwave with the forced cooling than in the heat treatment using a lamp heater. When the heat treatment temperature of the silicon substrate is the same, the thermal energy applied to the portions 67 of the surface of the wafer W′ doped with impurities is the same, so that the activation facilitation effect by the thermal energy becomes the same. Therefore, it is expected that the sheet resistance is the same. Accordingly, it is assumed that, in the heat treatment using a microwave with the forced cooling, the activation facilitation effect other than the activation facilitation effect by the thermal energy, i.e., the unique effect of facilitating activation due to the microwaves, is enhanced, and this results in the reduction of the sheet resistance.

Further, as the heat treatment temperature of the silicon substrate becomes lower, the difference in the sheet resistance between the heat treatment using a lamp heater and the heat treatment using a microwave with the forced cooling is increased. This is because the specific microwave effect which facilitates activation is enhanced as the heat treatment temperature of the silicon substrate is lower.

Meanwhile, in regards to most heat treatment temperatures of the silicon substrate, the sheet resistance of the heat treatment using a lamp heater and that of the heat treatment using a microwave without the forced cooling are substantially the same. Even in the heat treatment using a microwave without the forced cooling, the unique effect of microwaves which facilitates activation can be expected and, thus, the sheet resistance is decreased. Therefore, in the heat treatment using a microwave without the forced cooling, the heat by induction heating is not removed and the impurities are diffused by the heat. Accordingly, the amount of impurities that can substitute for silicon crystal lattice points is reduced and the sheet resistance is not particularly decreased.

In other words, in order to reduce the sheet resistance, the unique effect of microwaves which facilitates activation needs to be enhanced while suppressing the diffusion of impurities.

Further, in order to check the degree of diffusion of impurities, the concentration of impurities was measured in a silicon substrate that had been subjected to heat treatment using a lamp heater and a silicon substrate that had been subjected to heat treatment using a microwave with the forced cooling.

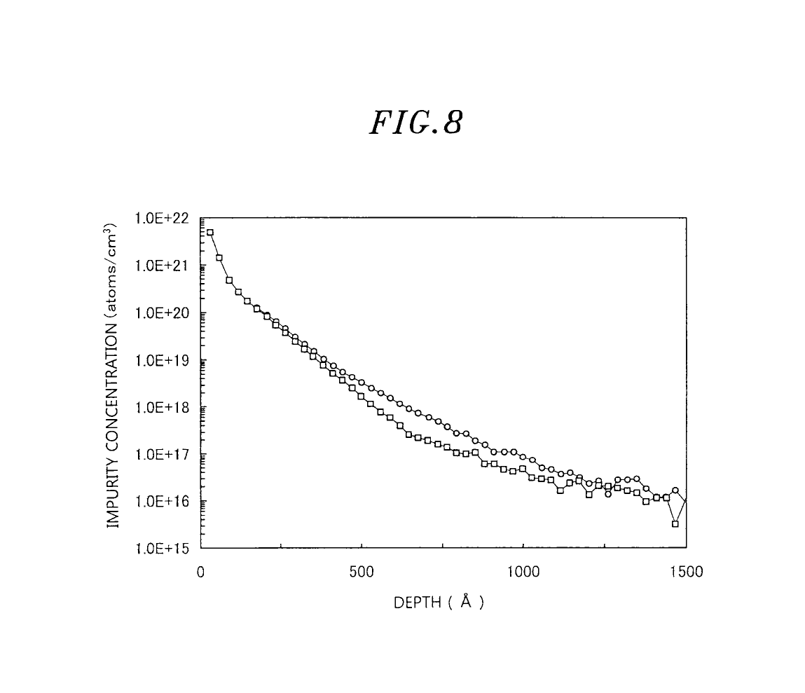

FIG. 8 is a graph showing the degree of diffusion of impurities in the heat treatment using a lamp heater and in the heat treatment using a microwave with the forced cooling. The vertical axis indicates a concentration of impurities, and the horizontal axis indicates a depth from a surface of a substrate silicon. The impurity concentration measured in the heat treatment using a lamp heater is indicated by ┌◯┘; and the impurity concentration measured in the heat treatment using a microwave with the forced cooling is indicated by ┌□┘.

As can be seen from FIG. 8, at all depths, the impurity concentration was lower in the heat treatment using a microwave with the forced cooling than in the heat treatment using a lamp heater. In other words, by forcedly cooling the silicon substrate, the heat by induction heating can be removed and the diffusion of impurities by the heat can be suppressed.

The present invention has been conceived based on the above information.

In the method for processing an object in accordance with the present embodiment, the microwaves (indicated by thin arrows in FIG. 6) scattering in the processing chamber 31 are omnidirectionally irradiated to the wafer W′ which is supported by the pins 50 of the arms 44 and has on the surface thereof the portions 67 doped with impurities. The irradiated microwaves are absorbed by the wafer W′, and the impurities doped on the portions 67 can substitute for silicon crystal lattice points. At this time, the unique effect of microwaves which facilitates activation is realized, so that the activation of impurities is facilitated compared to the activation by thermal energy. Therefore, the resistance of the portions 67 can be further reduced.

Moreover, in the method for processing an object in accordance with the present embodiment, an eddy current is generated at a wafer W′ by the microwave, and heat is generated by the flow of the eddy current through the wafer W′. Since, however, the cooling gas introduced into the processing chamber 31 (indicated by thick arrows in FIG. 6) along the surface of the wafer W′, the heat generated by the eddy current is removed. In other words, the wafer W′ is forcedly cooled by the cooling gas. Accordingly, the diffusion of impurities by heat can be suppressed, and the activation of impurities at the portions 67 can be reliably carried out.

While the invention has been shown and described with respect to the embodiments, it will be understood by those skilled in the art that various changes and modification may be made without departing from the scope of the invention as defined in the following claims.

What is claimed is:

1. A method for processing an object by heating the object, comprising:
irradiating microwaves to the object, wherein the object is forcedly cooled.

2. The method of claim 1, wherein, in said irradiating the microwaves, a surface of the object is forcedly cooled.

3. The method of claim 1, wherein the object has amorphous silicon and the amorphous silicon is crystallized in said irradiating the microwaves.

4. The method of claim 2, wherein the object has amorphous silicon and the amorphous silicon is crystallized in said irradiating the microwaves.

5. A method for processing an object by heating the object having amorphous silicon, comprising:
crystallizing the amorphous silicon by irradiating microwaves to the object, which includes generating crystal nuclei at the silicon amorphous; and growing the generated crystal nuclei,
wherein, at least in said growing the crystal nuclei, the object is forcedly cooled.

6. The method of claim 5, wherein a temperature of the object in the crystal nucleus growth is set to be lower than a temperature of the object in said generating the crystal nuclei.

7. The method of claim 1, wherein the object has portions doped with impurities, and the impurities doped on the portions are activated in said irradiating the microwaves.

8. The method of claim 2, wherein the object has portions doped with impurities, and the impurities doped on the portions are activated in said irradiating the microwaves.

9. The method of claim 1, wherein the microwaves have a frequency of 5.8 GHz.

10. The method of claim 2, wherein the microwaves have a frequency of 5.8 GHz.

11. The method of claim 3, wherein the microwaves have a frequency of 5.8 GHz.

12. The method of claim 4, wherein the microwaves have a frequency of 5.8 GHz.

13. The method of claim 5, wherein the microwaves have a frequency of 5.8 GHz.

14. The method of claim 6, wherein the microwaves have a frequency of 5.8 GHz.

15. The method of claim 7, wherein the microwaves have a frequency of 5.8 GHz.

16. The method of claim 8, wherein the microwaves have a frequency of 5.8 GHz.
